(19) United States
(12) Patent Application Publication
(10) Pub. No.: US 2006/0105530 A1
(43) Pub. Date: May 18, 2006

(54) Method for fabricating semiconductor device

(75) Inventors: Chao-Sung Lai, Yilan County (TW); Woei-Cherng Wu, Hsinchu County (TW); Jer-Chyi Wang, Taoyuan County (TW); Kung-Ming Fan, Taoyuan County (TW); Shian-Jyh Lin, Chiayi County (TW)

Correspondence Address: QUINTERO LAW OFFICE, 1617 BROADWAY, 3RD FLOOR, SANTA MONICA, CA, 90404, US

(73) Assignee: NANYA TECHNOLOGY CORPORATION, TAOYUAN (TW)

(21) Appl. No.: 10/986,692

(22) Filed: Nov. 12, 2004

(51) Int. Cl. H01L 21/336

(52) U.S. Cl. 438/287

(57) ABSTRACT

A method for fabricating a semiconductor device with high-k materials. A high-k dielectric layer is formed on a substrate, followed by a fluorine-containing treatment of the high-k dielectric layer, forming an interface containing Si—F bonds.

### BACKGROUND

The invention relates to a method for fabricating a semiconductor device, and more particularly, to a method for fabricating a semiconductor device with high-k dielectric materials.

As semiconductor devices, such as metal oxide semiconductor field effect transistors (MOSFETs), are scaled down, ultra thin SiO₂ gate oxide dielectric films that form portions of the devices may exhibit undesirable current leakage. In order to minimize current leakage while maintaining high drive current, high equivalent oxide thickness (EOT) may be achieved by using thinner films with high dielectric constant (k). One method of reducing the EOT is to place a high-k dielectric film immediately over the gate of a MOSFET or over the area where the high-k becomes the gate of a MOSFET.

FIG. 1A is a cross section of a conventional MOSFET with high-k gate dielectric layer. The conventional MOSFET comprises source/drain regions 18 located in a semiconductor substrate 10 and separated by a channel region 15. A gate electrode 16 layer overlies the channel region 15 and is separated by an insulator layer 14 with high-k dielectric materials. A native oxide layer 12 is substantially formed on the substrate 10 creating an interface 11 comprising Si—O, or dangling bonds, as shown in FIG. 1B.

Native oxide layer 12, however, formed between the silicon substrate 10 and the high-k dielectric layer 14 may not have the electrical properties needed for a particular device design. One problem which has been reported relating to integration of high-K dielectric materials is oxidation of silicon by certain high-K dielectric materials when the high-K dielectric material is formed directly on a silicon substrate. Since oxidation results in formation of what may be referred to as a “standard-k” dielectric material, i.e., silicon dioxide, some of the benefit of the high-k dielectric material can be lost. In addition, reactions considered adverse between the high-k dielectric material and silicon, silicon dioxide or other standard-k dielectric materials may also occur.

Accordingly, post processing ameliorating or inhibiting formation of native oxide layer is desirable.

### SUMMARY

Embodiments of the invention are directed to a fabrication method of a metal oxide semiconductor field effect transistor (MOSFET) with a high-k dielectric layer by performing a fluorine-containing process on the high-k dielectric layer to create an interface containing Si—F bonds.

Embodiments of the invention provide a method for fabricating a semiconductor device with high-k materials. A substrate is provided. A high-k dielectric layer is formed on the substrate, followed by a fluorine containing process on the high-k dielectric layer to create an interface containing Si—F bonds.

Alternatively, a CF₄ plasma treatment on the high-k dielectric layer can be used to create the interface containing Si—F bonds, wherein a gate electrode layer is formed overlying the high-k dielectric layer.

A sacrificial layer may also be formed on the high-k dielectric layer with implantation of F-ions on the high-k dielectric layer creating the interface containing Si—F bonds, after which the sacrificial layer is removed, and a gate electrode layer is formed overlying the high-k dielectric layer.

### BRIEF DESCRIPTION OF THE DRAWINGS

The invention can be more fully understood by reading the subsequent detailed description in conjunction with the examples and references made to the accompanying drawings, wherein:

FIG. 1A is a cross-section of a conventional MOSFET with high-k gate dielectric layer;

FIG. 1B is a schematic showing an interface between native oxide layer and substrate of the conventional MOSFET;

FIGS. 2A to 2E are schematic cross-sections illustrating a method for fabricating a semiconductor device with high-k materials according to embodiments of the invention;

FIG. 3 is a schematic showing an interface between high-k dielectric layer and substrate of a MOSFET according to embodiments of the invention;

FIGS. 4A to 4D are schematic cross-sections illustrating another method for fabricating a semiconductor device with high-k materials according to embodiments of the invention; and

FIGS. 5A to 5E are schematic cross-sections illustrating still another method for fabricating a semiconductor device with high-k materials according to embodiments of the invention.

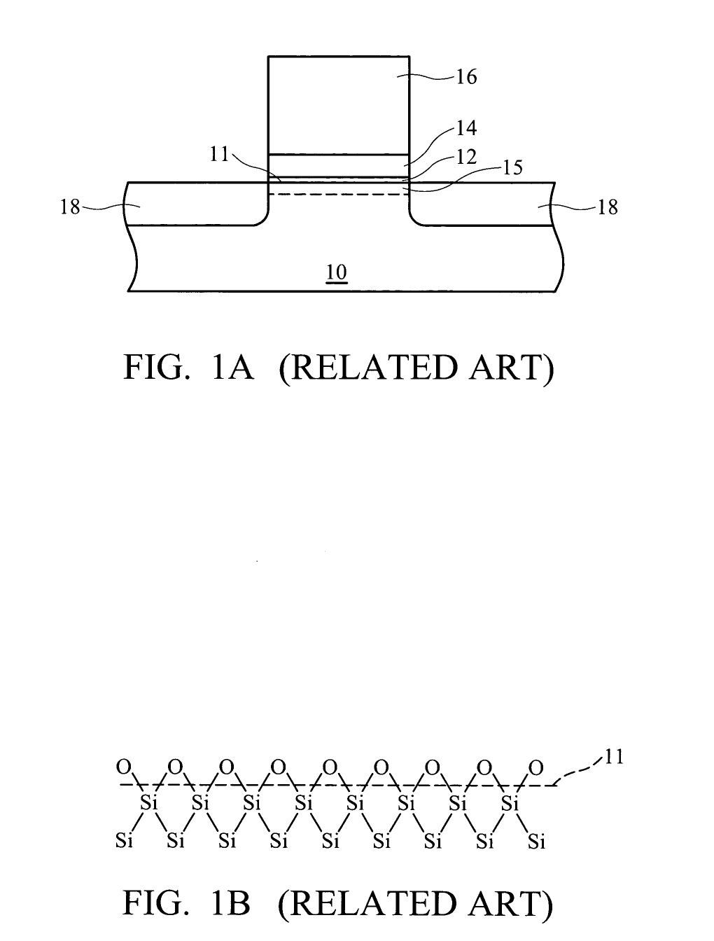

### DETAILED DESCRIPTION

In the following description, a number of details are set forth to provide a thorough understanding of embodiments of the invention. It will be apparent to those skilled in the art, however, that the invention may be practiced in many ways other than those expressly described here. The invention is thus not limited by the specific details disclosed below.

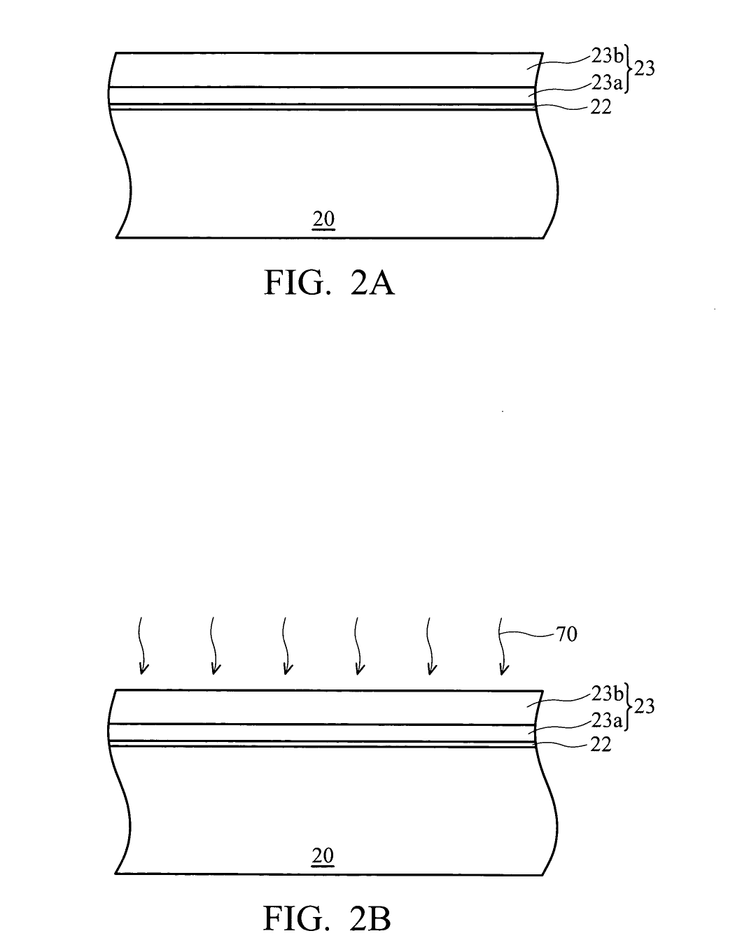

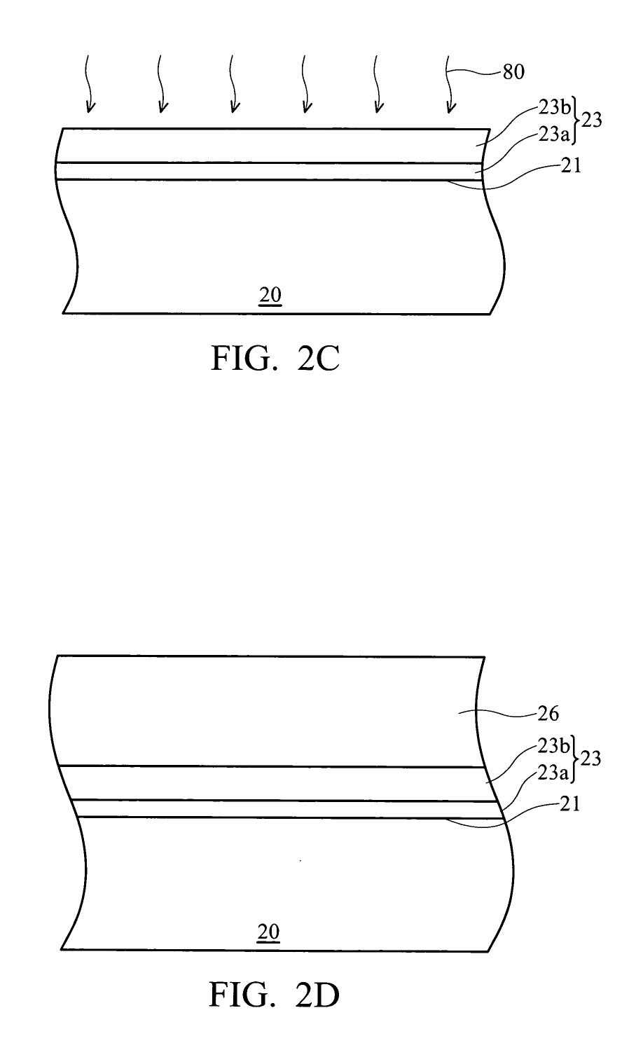

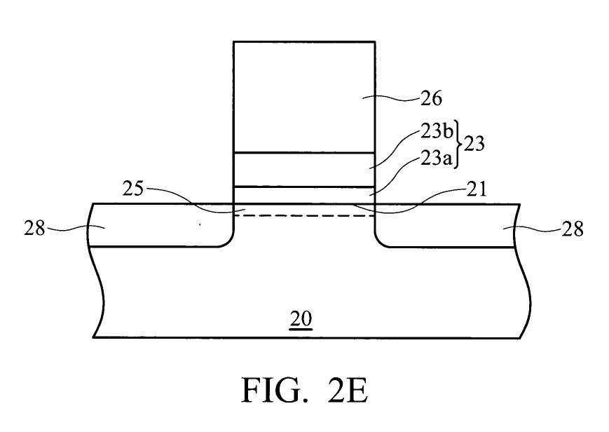

FIGS. 2A to 2E are schematic cross-sections illustrating a method for fabricating a semiconductor device with high-k materials according to embodiments of the invention. Referring to FIG. 2A, at least one high-k gate dielectric layer 23 is formed on substrate 20. Substrate 20 may comprise a bulk silicon or silicon-on-insulator substructure. Alternatively, substrate 20 may comprise other materials, which may or may not be combined with silicon, such as germanium, indium antimonide, lead telluride, indium arsenide, indium phosphide, gallium arsenide, or gallium antimonide. Although several examples of materials from which substrate 20 may be formed are disclosed, any material that serves as a foundation upon which a semiconductor device may be built falls within the spirit and scope of the present invention.

When substrate 20 comprises a silicon wafer, the wafer is cleaned before formation of the high-k gate dielectric layer 23, with a water/H₂O₂/NH₄OH solution to remove particles and organic contaminants, and a water/H₂O₂/HCl solution to remove metallic contaminants.

After cleaning, at least one high-k gate dielectric layer 23 such as an Hf-silicate layer 23a and a HfO₂ layer is formed on the substrate 20. High-k gate dielectric layer 23 comprises a material with a dielectric constant exceeding that of silicon dioxide, preferably HfO₂, Hf-silicate, or combinations thereof.

High-k gate dielectric layer 23 is formed on substrate 20 by conventional deposition such as atomic layered deposition (ALD), chemical vapor deposition (CVD), low pressure CVD, or physical vapor deposition (PVD). Preferably, conventional atomic layer CVD is used. In most applications, high-k gate dielectric layer 23 is thinner than about 60 Å, and more preferably between about 5 and 40 Å.

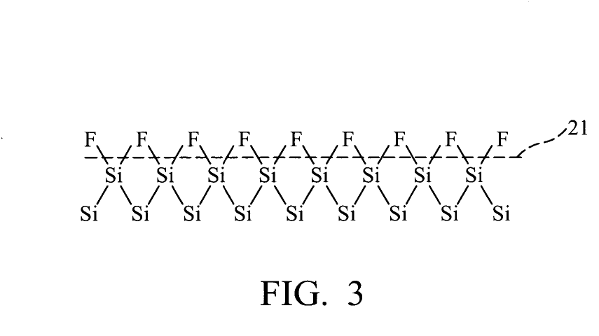

As deposited, plasma treatment 70 containing CF₄ plasma is performed on the high-k gate dielectric layer 23. Native oxide layer 22 is removed leaving an interface 21 containing Si—F bonds. Electron spectroscopy chemical analysis (ESCA) of the interface 21 between the substrate and the high-k dielectric layer shows increased Si—F bonds after CF₄ treatment 70, as shown in FIG. 3.

Referring to FIG. 2C, annealing 80 is performed at about 700° C. to 1150° C., using rapid thermal annealing (RTA), performed for a few seconds to a few minutes. Annealing time here is sufficient to form a densified and homogeneous high-K dielectric material. The annealing step 80 may be carried out in an atmosphere comprising N₂, NO, N₂O, or mixtures thereof. The annealing step 80 may also be carried out at a reduced pressure, under a vacuum down to approximately 10⁻⁴ Torr.

Referring to FIG. 2D, a conductive layer 26 is formed on the high-k dielectric layer 23. The conductive layer may be such as titanium nitride (TiN), aluminum (Al), tungsten (W), a heavily doped polysilicon, or combinations thereof. The conductive layer 26, for example, can be formed by chemical vapor deposition (CVD) with a thickness of approximately 50 to 3000 Å.

Referring to FIG. 2E, the conductive layer 26 and the high-k dielectric layer 23 are patterned to form the gate for the transistor, using conventional lithographic and etching processes. Note that a protective layer such as SiO₂′ or Si₃N₄ is preferably formed on the conductive layer before lithographic and etching processes. Following definition of the gate, ions are implanted into the semiconductor substrate 20 to form source/drain regions 28. A MOSFET with high-k dielectric materials is thus formed.

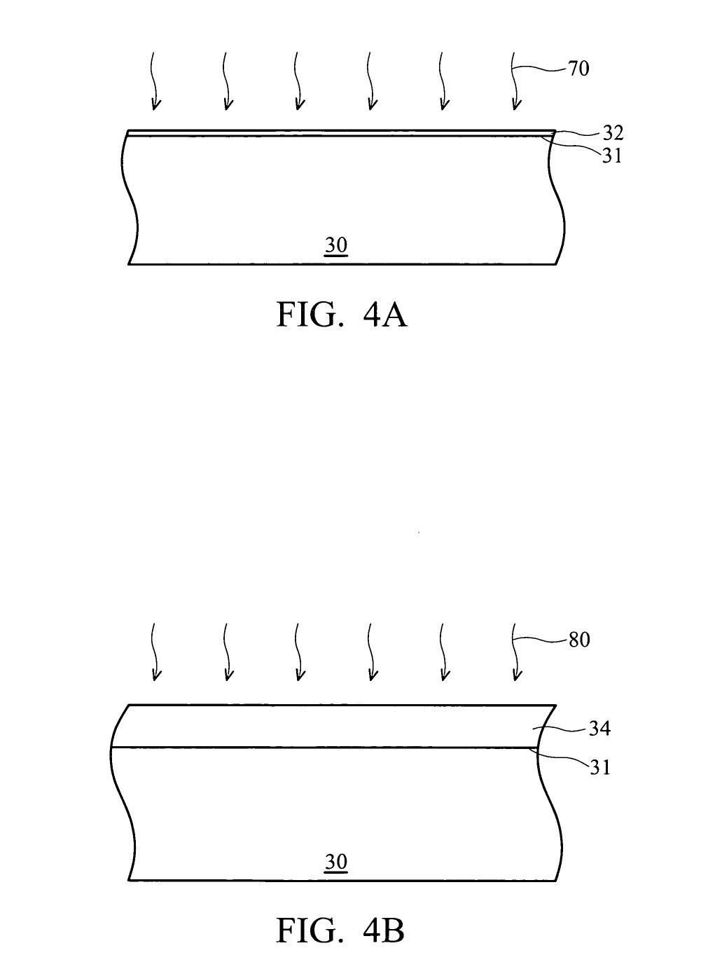

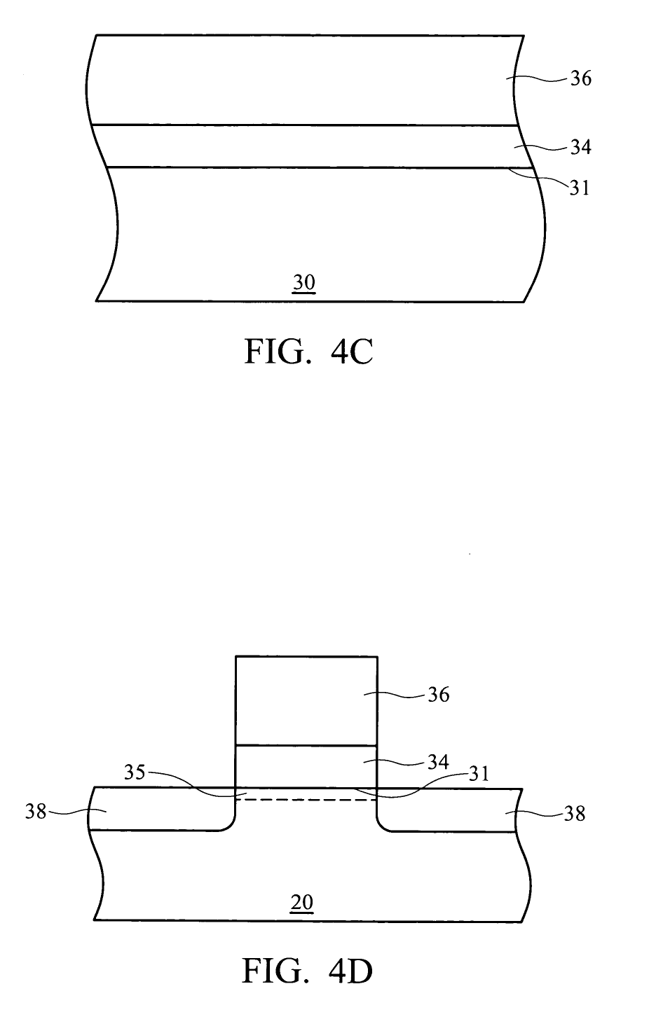

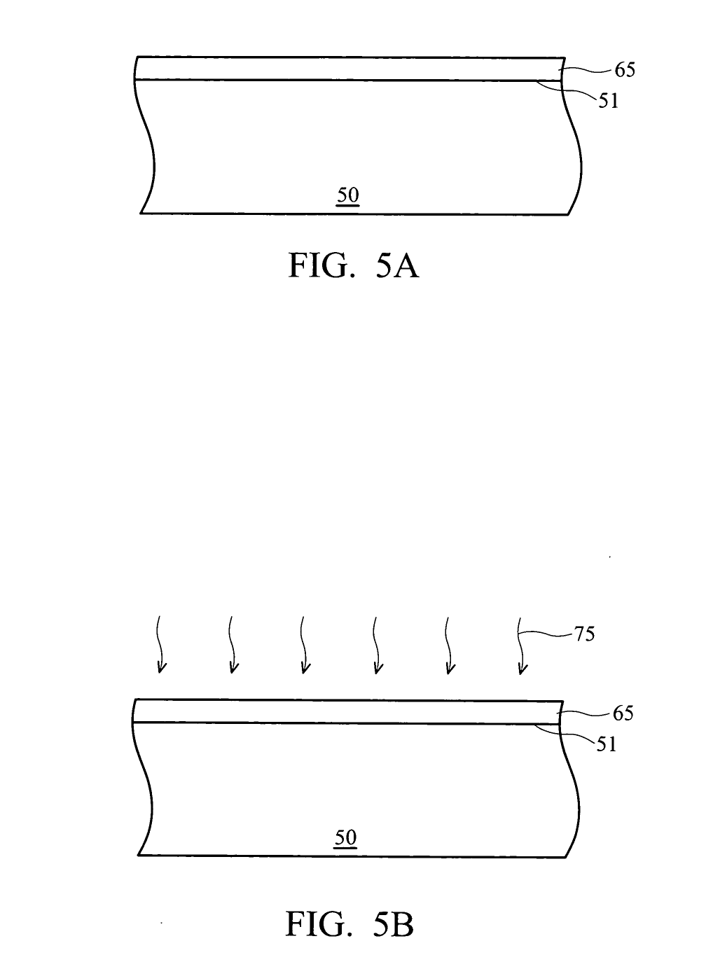

Alternatively, as shown in FIG. 4A, after cleaning, plasma treatment 70 containing CF₄ can be performed on the surface of a substrate 30. Here, native oxide layer 32 is removed leaving a surface 31 containing Si—F bonds. Electron spectroscopy chemical analysis (ESCA) shows increased Si—F bonds with the implementation of CF₄ treatment 70.

Referring to FIG. 4B, at least one high-k gate dielectric layer 34 is formed on substrate 30, comprising material with a dielectric constant exceeding that of silicon dioxide, preferably HfO₂, Hf-silicate, or combinations thereof.

High-k gate dielectric layer 34 may be formed on substrate 30 using conventional methods, such as atomic layered deposition (ALD), chemical vapor deposition (CVD), low pressure CVD, or physical vapor deposition (PVD). Preferably, conventional atomic-layer CVD is used. Preferably, high-k gate dielectric layer 34 is less than about 100 Å, and more preferably between about 5 and 40 Å.

Annealing 80 is carried out at about 700° C. to 1150° C., using, for example, rapid thermal annealing (RTA) technique, for a few seconds to a few minutes, sufficient to form a densified and homogeneous high-K dielectric material. Annealing 80 is carried out in an atmosphere comprising N₂, NO, N₂O or mixtures thereof, alternatively at a reduced pressure, under a vacuum down to approximately 10⁻⁴ Torr.

Referring to FIG. 4C, a conductive layer 36 is formed on the high-k dielectric layer 34, of titanium nitride (TiN), aluminum (Al), tungsten (W), heavily doped polysilicon, or combinations thereof by chemical vapor deposition (CVD) at a thickness from about 50 to 3000 Å.

Referring to FIG. 4D, the conductive layer 36 and the high-k dielectric layer 34 are patterned to form the gate for the transistor, using conventional lithographic and etching processes. Note that a protective layer such as SiO₂ or Si₃N₄ is preferably formed on the conductive layer before lithographic and etching processes. Following definition of the gate, ions are implanted into the semiconductor substrate 30 to form source/drain regions 38. A MOSFET with high-k dielectric materials is thus formed.

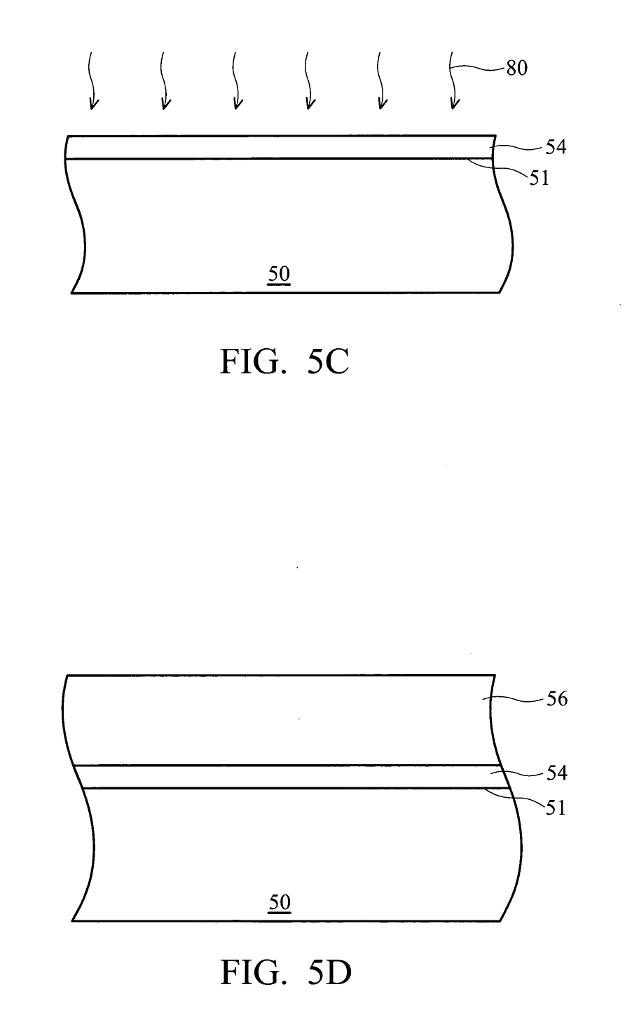

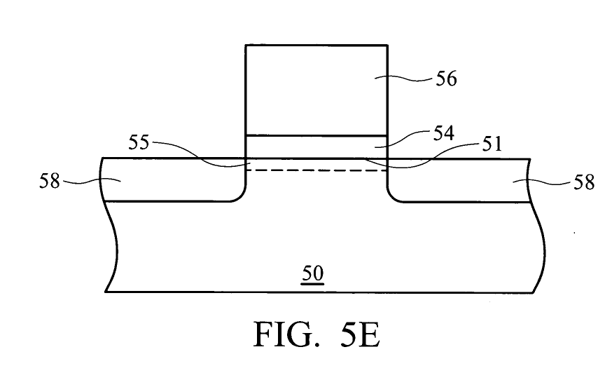

Alternatively, as shown in FIG. 5A to 5E, after cleaning, a sacrificial layer 65 is deposited on a substrate, of silicon oxide, silicon nitride, silicon oxynitride, or combination thereof.

As shown in FIG. 5B, F-ion implantation 75 is performed on the substrate 50, preferably from about 1E13 to 1E15 breaking Si—O bonds and forming an interface 51 containing Si—F bonds.

Referring to FIG. 5C, the sacrificial layer 65 is removed, followed by formation of at least one high-k gate dielectric layer 54 on substrate 50. High-k gate dielectric layer 54 comprises a dielectric constant exceeding that of silicon dioxide, preferably HfO₂, Hf-silicate, or combinations thereof.

High-k gate dielectric layer 54 is formed on substrate 50 using conventional deposition, such as atomic layered deposition (ALD), chemical vapor deposition (CVD), low pressure CVD, or physical vapor deposition (PVD). Preferably, conventional atomic layer CVD is used. High-k gate dielectric layer 54 is preferably less than about 60 Å, and more preferably between about 5 and 40 Å.

Annealing 80 is carried out at about 700° C. to 1150° C., using, for example, rapid thermal annealing (RTA) technique for a few seconds to a few minutes, sufficient to form a densified and homogeneous high-K dielectric material. Annealing 80 is carried out in an atmosphere comprising N₂, NO, N₂O or mixtures thereof, alternatively at a reduced pressure, under a vacuum down to approximately 10⁻⁴ Torr.

Referring to FIG. 5D, a conductive layer 56 is formed on the high-k dielectric layer 54, of titanium nitride (TiN), aluminum (Al), tungsten (W), heavily doped polysilicon, or combinations thereof, by chemical vapor deposition (CVD) at a thickness from about 500 to 3000 Å.

Referring to FIG. 5E, the conductive layer 56 and the high-k dielectric layer 54 are patterned to form the gate for the transistor, using conventional lithographic and etching processes. Note that a protective layer such as SiO₂ or Si₃N₄ is preferably formed on the conductive layer before lithographic and etching processes. Following definition of the gate, ions are implanted into the semiconductor substrate 50 to form source/drain regions 58. A MOSFET with high-k dielectric materials is thus formed.

Fabrication of a MOSFET with high-k dielectric materials according to embodiment of the inventions may provides improved capacitance. Capacitance-gate voltage characteristics, gate current leakage, thermal stability, and stress induced leakage current (SILC) issues may be improved with implementation of F-ion implantation.

While the invention has been described by way of example and in terms of preferred embodiment, it is to be understood that the invention is not limited thereto. On the contrary, it is intended to cover various modifications and similar arrangements as would be apparent to those skilled in the art. Therefore, the scope of the appended claims should be accorded the broadest interpretation so as to encompass all such modifications and similar arrangements.

1-7. (canceled)

8. A method for fabricating a semiconductor device with high-k materials, comprising:
providing a semiconductor substrate;
forming a high-k dielectric layer on the substrate;
performing a CF₄ plasma treatment on the high-k dielectric layer to create an interface containing Si—F bonds; and
forming a gate electrode layer over the high-k dielectric layer.

9. The method as claimed in claim 8, wherein the high-k dielectric layer comprises HfO₂, Hf-silicate, or combinations thereof.

10. The method as claimed in claim 8, wherein the substrate comprises a native oxide thereon.

11-12. (canceled)

13. The method as claimed in claim 8, further comprising annealing the substrate after the CF₄ plasma treatment.

14. The method as claimed in claim 8, further comprising forming a source and a drain region in the substrate.

15. A method for fabricating a semiconductor device with high-k materials, comprising:
providing a semiconductor substrate;
forming a high-k dielectric layer on the semiconductor substrate;
forming a sacrificial layer on the semiconductor substrate;
implanting F-ions into the high-k dielectric layer to create an interface containing Si—F bonds between the high-k dielectric layer and the semiconductor substrate;
removing the sacrificial layer; and
forming a gate electrode layer over the high-k dielectric layer.

16. The method as claimed in claim 15, wherein the high-k dielectric layer comprises HfO₂, Hf-silicate, or combinations thereof.

17. The method as claimed in claim 15, wherein the semiconductor substrate comprises a native oxide thereon.

18. The method as claimed in claim 15, wherein the sacrificial layer is a silicon oxide layer.

19. The method as claimed in claim 15, further comprising annealing the substrate after implantation.

20. The method as claimed in claim 15, further comprising forming a source and a drain region in the substrate.
